(19) United States
(12) Patent Application Publication
(10) Pub. No.: US 2008/0037799 A1
(43) Pub. Date: Feb. 14, 2008

(54) APPARATUS AND METHOD OF EQUALIZING A ROOM PARAMETER IN AN AUDIO SYSTEM USING AN ACOUSTIC TRANSDUCER ARRAY

(75) Inventors: Sergey Yarygin, Krasnodar (RU); Vladislav Shimanskiy, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/668,128

(22) Filed: Jan. 29, 2007

(30) Foreign Application Priority Data
Aug. 11, 2006 (KR) 10-2006-0076365

(51) Int. Cl. H03G 3/00

(52) U.S. Cl. 381/63; 381/61

(57) ABSTRACT

An apparatus and method of enabling equalization of a room parameter with a simple structure and low cost in an audio system using an acoustic transducer array. The apparatus to equalize a room parameter includes an audio signal generation unit to generate two identical audio signals, an audio signal modification unit to modify the audio signals, a sound beam generation unit to transform each of the two modified signals into a sound, to directly transmit one sound to the position of a listener, and to transmit the other sound to the position of the listener such that the other sound is reflected from a reflecting object and transmitted to the position of the listener, a sound magnitude determination unit to collect a sound generated through synthesis of the two sounds at the position of the listener, and a control unit to obtain a delay constant and a filter coefficient.

### CROSS-REFERENCE TO RELATED APPLICATIONS

This application claims priority under 35 U.S.C. § 119(a) from Korean Patent Application No. 10-2006-0076365 filed on Aug. 11, 2006, in the Korean Intellectual Property Office, the disclosure of which is incorporated herein in its entirety by reference.

### BACKGROUND OF THE INVENTION

1. Field of the Invention

The present general inventive concept relates to an audio system, and more particularly, to an apparatus and method of equalizing a room parameter in an audio system using an acoustic transducer array.

2. Description of the Related Art

An acoustic transducer array is an apparatus for generating sound by using a plurality of acoustic transducers. A representative example of the acoustic transducer array is a speaker array. However, the present invention is not limited to the speaker array and can be applied to any device that can transform an audio signal to a sound beam having directivity.

FIG. 1 is a diagram illustrating an operation of an acoustic transducer array according to a conventional technology.

An acoustic transducer array 10 is made to generate an imaginary source 18 by using a reflecting object 20, such as a wall or ceiling of a room.

There are many general inventive concepts related to the acoustic transducer array 10 having two purposes. The first purpose is to generate a sound localized at a predetermined place, and the second purpose other is to simulate a variety of sound sources. For example, instead of positioning two separate speakers to the right and left of a listener 12, a speaker array can be used so that the listener 12 can experience a stereo sound effect.

An electrical signal (hereinafter referred to as an “audio signal”) provided to the speaker array 10 is transformed into sound in the speaker array 10. The sound is reflected by the reflecting object 20, and then a reflected sound 16 arrives at the position of the listener 12. Sound having directivity for a predetermined purpose is referred to as a sound beam.

The audio signal to generate the reflected sound 16 should be filtered before being output as a sound, to compensate for effects resulting due to the reflecting object 20 (wall or ceiling). The effect of the reflecting object which includes distortion of the sound is referred to as a room parameter.

The room parameter is not known in advance and a room parameter value varies with respect to a given environment, i.e., a room. Accordingly, a room parameter is directly measured, and a filter parameter is determined according to a conventional technology.

FIG. 2 is a block diagram of an apparatus to measure a room parameter according to a conventional technology.

Referring to FIG. 2, a noise generated in a noise generator 31 is transferred to a speaker 34 through a digital-to-analog converter (DAC) 32 and an amplifier 33. The speaker 34 is set to face the same direction as the direction that a sound beam to measure a room parameter is output.

The sound output from the speaker 34 is reflected by a reflecting object 20 and is collected by a microphone 35. The signal collected by the microphone 35 is converted into a digital signal by an analog-to-digital converter (ADC) 36 and input to an analyzer 37. The analyzer 37 analyzes a correlation between noise and the collected signal and determines a room parameter

Accordingly, a reflected sound is directly collected and analyzed, thereby obtaining a room parameter, and from the room parameter, a filter parameter is obtained. Accordingly, complicated calculations may be performed. To obtain the room parameter, a digital signal processor (DSP) 38 to perform the complicated calculations, such as correlation calculations, is required. This complex structure also makes the cost of the apparatus expensive.

In addition, to transfer the collected sound to an audio system 30, wires are required and the listener experiences an inconvenience of connecting wires.

### SUMMARY OF THE INVENTION

The present general inventive concept provides an apparatus and method of equalizing a room parameter with a simple structure and low cost in an audio system using an acoustic transducer array.

The present general inventive concept also provides a computer readable recording medium having embodied thereon a computer program to execute the method of equalizing a room parameter.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept are achieved by providing an apparatus to equalize a room parameter in an audio system using an acoustic transducer array, the apparatus including, an audio signal generation unit to generate two identical audio signals, an audio signal modification unit to modify the audio signals, thereby generating the two signals to have opposite phases, with one of the two signals being delayed from the other signal for a time period corresponding to a predetermined delay constant and the other signal being filtered, and to provide the two modified signals to a sound beam generation unit, the sound beam generation unit to transform each of the two modified signals into a sound, and to directly transmit one sound to a position of a listener and to transmit the other sound to the position of the listener such that the other sound is reflected from a reflecting object before being transmitted to the position of the listener, a sound magnitude determination unit to collect a sound generated through synthesis of the two sounds at the position of the listener and to determine a magnitude of the sound, and a control unit to obtain a delay constant and a filter coefficient to make the magnitude of the synthesized sound a minimum among a plurality of delay constant values and filter coefficient values, by making the audio signal generation unit, the audio signal modification unit, the sound beam generation unit, and the second magnitude determination unit iteratively operate.

The foregoing and/or other aspects and utilities of the present general inventive concept may also be achieved by providing a method of equalizing a room parameter in an audio system using an acoustic transducer array, the method including, generating two identical audio signals having opposite phases, with one of the two signals being delayed from the other signal for a time period corresponding to a predetermined delay constant and the other signal being filtered, transforming each of the two modified signals into a sound, and directly transmitting one sound to a position of a listener and transmitting the other sound to the position of the listener such that the other sound is reflected from a reflecting object and transmitted to the position of the listener, collecting a sound generated through synthesis of the two sounds at the position of the listener and determining a magnitude of the sound, and obtaining a delay constant and a filter coefficient making the magnitude of the synthesized sound a minimum, by performing operations to generate the audio signals, transmitting the sounds, and determining the magnitude of the sound, iteratively performed with respect to a plurality of delay constant values and filter coefficient values.

The foregoing and/or other aspects and utilities of the present general inventive concept may also be achieved by providing an apparatus to equalize a room parameter in an audio system using an acoustic transducer array, the apparatus including an audio signal modification unit to modify two identical audio signals to generate two signals having opposite phases, wherein one of the signals is delayed, a sound beam generation unit to transform each of the two modified signals into a sound, and to directly transmit the sound corresponding to the delayed signal to a position of a listener and to transmit the other sound to the position of the listener such that the other sound is reflected from a reflecting object before being transmitted to the position of the listener, a sound magnitude determination unit to synthesize the two sounds at the position of the listener and to determine a magnitude of the synthesized sound, and a control unit to obtain a delay constant and a filter coefficient to make the magnitude of the synthesized sound a minimum value among a plurality of delay constant values and filter coefficient values.

The foregoing and/or other aspects and utilities of the present general inventive concept may also be achieved by providing an apparatus to equalize a room parameter in an audio system using an acoustic transducer array, the apparatus including a sound beam generation unit to generate a first sound beam and a second sound beam from a first modified sound signal and a second modified sound signal, a control unit to control the first sound beam and the second sound beam to arrive at a position of a listener at the same time, wherein the first sound beam directly travels to the listener, and to obtain a filter coefficient to produce a minimum magnitude of a sound that is produce by combining the first sound beam and the second sound beam.

The second sound beam may reflect from an object before arriving at the position of the listener.

The control unit may delay the first sound for a time period corresponding to a delay constant, so that the first sound beam and the second sound beam arrive at the position of the listener at the same time.

The foregoing and/or other aspects and utilities of the present general inventive concept may also be achieved by providing a method of equalizing a room parameter in an audio system using an acoustic transducer array the method including modifying two identical audio signals to generate two signals having opposite phases, wherein one of the signals is delayed, transforming each of the two modified signals into a sound, transmitting the sound corresponding to the delayed signal to a position of a listener and transmitting the other sound to the position of the listener such that the other sound is reflected from a reflecting object before being transmitted to the position of the listener, synthesizing the two sounds at the position of the listener determining a magnitude of the synthesized sound, and obtaining a delay constant and a filter coefficient to make the magnitude of the synthesized sound a minimum value among a plurality of delay constant values and filter coefficient values.

The foregoing and/or other aspects and utilities of the present general inventive concept may also be achieved by providing a method of equalizing a room parameter in an audio system using an acoustic transducer array, the method including generating a first sound beam and a second sound beam from a first modified sound signal and a second modified sound signal, controlling the first sound beam and the second sound beam to arrive at a position of a listener at the same time, wherein the first sound beam directly travels to the listener, and obtaining a filter coefficient to produce a minimum magnitude value of a sound that is produced by combining the first sound beam and the second sound beam.

The producing of the minimum magnitude value of the combined sound beams may be performed by obtaining the filter coefficient by iteratively performing operations to generate audio signals, to modify audio signals, to generate sound beams, and to determine a magnitude of a sound with respect to a plurality of delay constants.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a diagram illustrating an operation of an acoustic transducer array according to a conventional technology;

FIG. 2 is a block diagram of an apparatus to measure a room parameter according to a conventional technology;

FIG. 3 is a block diagram of an apparatus to equalize a room parameter according to an embodiment of the present general inventive concept;

FIGS. 4A and 4B are a flowchart of a method of equalizing a room parameter according to an embodiment of the present general inventive concept;

FIG. 5 is a diagram illustrating examples of waveforms of sounds generated in a sound beam generation unit, the waveforms appearing at the position of a listener, according to an embodiment of the present general inventive concept; and

FIG. 6 is a diagram illustrating a process of equalizing a room parameter by a filter according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

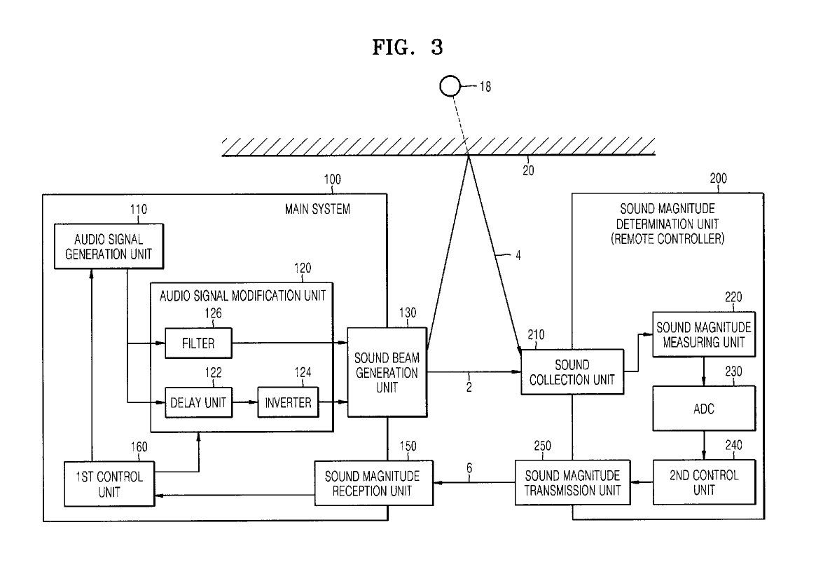

FIG. 3 is a block diagram of an apparatus to equalize a room parameter according to an embodiment of the present general inventive concept.

Referring to FIG. 3, the apparatus to equalize a room parameter may include an audio signal generation unit 110, an audio signal modification unit 120, a sound beam generation unit 130, a sound magnitude reception unit 150, a first control unit 160, and a sound magnitude determination unit 200.

An audio system may include a main system 100 and a remote controller.

The main system 100 is a main body of the audio system, and generates an audio signal to provide the audio signal to an acoustic transducer array, thereby generating a sound. The audio signal generation unit 110, the audio signal modification unit 120, the sound beam generation unit 130, the sound magnitude reception unit 150 and the first control unit 160, according to the current embodiment of the present general inventive concept, may be included in the main system 100.

A remote controller is a remote control device to control functions of an audio system. The remote controller may be of a small size with a light weight, and may be operated by a user. The sound magnitude determination unit 200, according to the current embodiment of the present general inventive concept, may be included in the remote controller.

The remote controller uses an infrared channel to transmit a command to control the audio system. A device to receive an infrared signal from the remote controller is included in the main system 100.

The apparatus to equalize a room parameter, according to the current embodiment of the present general inventive concept, may eliminate a complicated structure as presented in the conventional apparatus to measure a room parameter, thereby reducing costs and eliminating inconvenience to a listener due to wiring between a microphone and an audio system.

According to the current embodiment of the present general inventive concept, a method to reduce complexity and cost of the apparatus by using a simple calculation, and in which a wire is not used between a microphone and an audio system, is suggested.

Unlike the conventional method in which a room parameter is calculated and then, by using a room parameter, a filter coefficient is further calculated, the present general inventive concept suggests a method of determining a filter coefficient capable of directly equalizing a room parameter.

Also, the present general inventive concept employs a structure in which a sound collection unit is disposed inside a remote controller of an audio system.

The audio signal generation unit 110 may generate two identical audio signals. Accordingly, an arbitrary audio signal is generated and the two signals are transferred to the audio signal modification unit 120.

The audio signal generation unit 110 may include an audio source of the audio system. For example, sound sources of an audio system, such as a cassette tape player, a CD player, a radio tuner, can be used as the audio signal generation unit 110.

Also, the audio system may be a part of a TV or a home theater system. Accordingly, the sound signal of the TV or the voice signal of the moving pictures can be used as an audio signal.

Thus, if the audio signal generation unit 110 directly uses the audio source of the audio system, a separate apparatus to generate an audio signal is not required and thus costs can be reduced.

A separate noise generator may also be used as the audio signal generation unit 110 to equalize a room parameter according to the current embodiment of the present general inventive concept.

The audio signal modification unit 120 modifies the two identical audio signals generated in the audio signal generation unit 110, and provides the two identical audio signals to the sound beam generation unit 130. The audio signal modification unit 120 delays one of audio signals, inverts the phase of the delayed signal, and filters the other audio signal.

The audio signal modification unit 120 may include a delay unit 122, an inverter 124, and a filter 126.

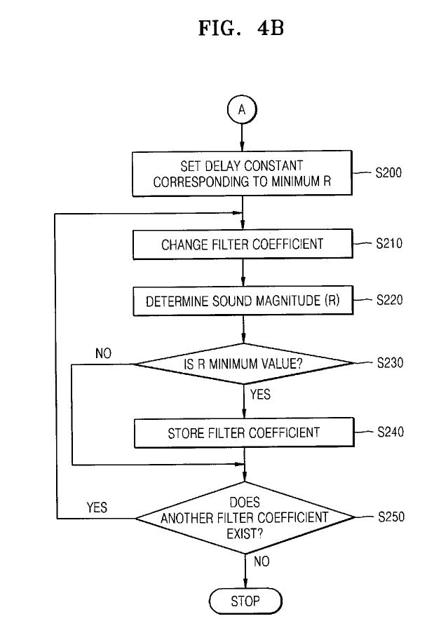

The delay unit 122 delays a given audio signal for a time period corresponding to a predetermined delay constant. Accordingly, the delay constant is specified in the first control unit 160. The delay unit 122 may delay an audio signal to generate a sound that is directly transferred to a position of a listener (without being reflected by a wall), of the two signals. If the sound to be transferred to the position of the listener is delayed and arrives at the listener at the time when the sound reflected by the wall arrives at the listener, a magnitude of a synthesized sound can be minimized. This will be explained later with reference to FIG. 5.

The inverter 124 inverts the phase of the input audio signal. In the example illustrated in FIG. 3, the audio signal output from the delay unit 122 is input to the inverter 124. The inverter 124 may also be disposed before the delay unit 122.

Also, the inverter 124 can be disposed beside the filter. Since the inverter 124 makes the phases of the two audio signals opposite to each other, any channel audio signal of the two channels can be inverted.

The filter 126 may equalize a room parameter. Accordingly, the filter 126 filters an input audio signal with respect to a given filter coefficient.

The two audio signals modified in the audio signal modification unit 120 are provided to the sound beam generation unit 130.

The sound beam generation unit 130 transforms an audio signal that is an electrical signal, into a sound beam with directivity.

The sound beam generation unit 130 according to the current embodiment may use an acoustic transducer array of an audio system. Accordingly, the equalization of the room parameter is done to provide an equalized audio signal to the acoustic transducer array of the audio system.

However, the sound beam generation unit 130 is not limited to the above functions, and any device that can transform an audio signal into a sound beam having directivity can function as the sound beam generation unit 130 of the present general inventive concept. For example, two speakers generating sounds having directivity can also be used.

Sounds generated in the sound beam generation unit 130 have two paths. A first sound 2 is a sound generated from the audio signal output from the delay unit 122 and is directly output to the position of the listener. A second sound 4 is a sound generated from the audio signal output from the filter 126, and is reflected by the reflecting object 20, and then arrives at the position of the listener.

At the position of the listener, a sound is generated through synthesis of the first sound 2 and the second sound 4 sounds.

The sound magnitude determination unit 200 collects the sound generated through the synthesis of the first sound 2 and the second sound 4 and determines the magnitude of the synthesized sound. The sound magnitude determination unit 200 may include a sound collection unit 210, a sound magnitude measuring unit 220, an analog-to-digital converter (ADC) 230, a second control unit 240 and a sound magnitude transmission unit 250.

The sound magnitude determination unit 200, according to the current embodiment of the present general inventive concept, may be included in the remote controller of the audio system. The sound magnitude transmission unit 250 may transmit the determined magnitude of the synthesized sound by using an infrared channel that is conventionally used in a remote controller to transmit a command to control an audio system.

Accordingly, the listener does not need to perform a separate operation to connect a microphone to the main system of the audio system. The apparatus to equalize a room parameter, according to the current embodiment of the present general inventive concept, may automatically obtain a required delay constant and filter coefficient to provide an equalized sound.

A separate synthesizing unit is not required to determine the magnitude of the synthesized sound in the sound magnitude determination unit 200. The sounds that are output from the sound beam generation unit 130 are transferred to the position of the listener as sound waves, and according to a principle of superposition of sound waves, a sound generated through synthesis of the two sounds arrives at the position of the listener. Accordingly, the synthesized sound is collected at the position of the listener. If the listener possesses the remote controller, the sound magnitude determination unit 200 is placed at the position of the listener.

The sound collection unit 210 collects the synthesized sound arriving at the position of the listener and transforms the sound into an electrical signal. The sound collection unit 210 may be a microphone. Any device that can transform a sound into an electrical signal can be the sound collection unit 210 according to the current embodiment of the present general inventive concept. Even without a separate manipulation of the listener, if the remote controller is placed at the position of the listener, the synthesized sound can be collected in a simple method by the sound collection unit 210.

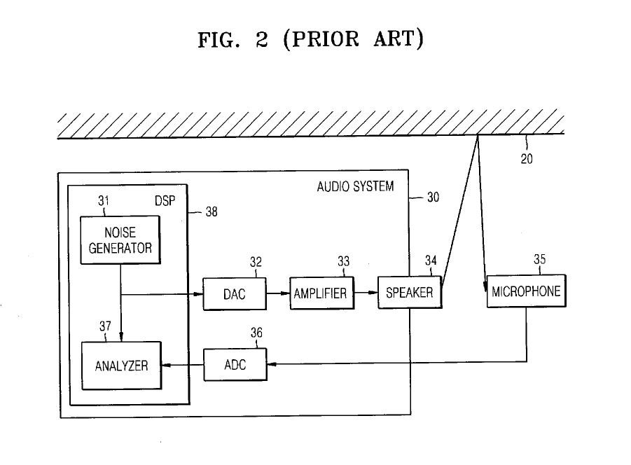

Referring to FIG. 2, the sound generated in the speaker is directly collected by the microphone, and a room parameter is calculated. The room parameter is obtained from the correlation between the noise generated in the noise generator 31 and the signal collected in the microphone 35. Accordingly, the microphone 35 should be of a high performance and quality. The microphone 35 should not distort the collected sound.

Referring to FIG. 3, the sound collection unit 210 is required to provide only a quality good enough to determine the magnitude of the synthesized sound. Accordingly, a microphone with a below-average quality can be used as the sound collection unit 210.

The sound magnitude measuring unit 220 measures the magnitude of the electrical signal transformed from the synthesized sound. Accordingly, a root mean square (RMS) measuring device which measures an RMS value of an output of the microphone or an amplitude detector may be used.

The magnitude of the sound signal measured in the sound magnitude measuring unit 220 may be converted into a digital signal in the ADC 230. is the conversion may be performed to produce the signal in a form that can be easily transmitted in the sound magnitude transmission unit 250.

The magnitude of the sound that is converted into the digital signal is transferred to the second control unit 240. The second control unit 240 transfers the magnitude to the sound magnitude transmission unit 250. The second control unit 240 may be identical to a microcontroller that generates a command in a remote controller to control an audio system.

The sound magnitude transmission unit 250 transfers a determined magnitude 6 of the sound to the main system 100. The sound magnitude transmission unit 250 may include an infrared (IR) signal transmission unit to transmit a magnitude of a synthesized sound by using an IR channel. However, the present general inventive concept may also include a radio frequency (RF) signal transmission unit to transfer the determined magnitude of the sound by using an RF channel.

Since only the magnitude of the sound is determined and transferred to the main system 100 without transferring the sound itself, the current embodiment of the present general inventive concept does not need the high quality microphone, wires, and complicated processors that are used in the conventional technology. Accordingly, the sound magnitude determination unit 200 can be included inside the remote controller and thus can provide convenience to the listener.

The sound magnitude reception unit 150 receives the magnitude of the synthesized sound determined and transferred by the sound magnitude determination unit 200. The reception method of the sound magnitude reception unit 150 is determined according to the transmission method of the sound magnitude transmission unit 250. For example, if the sound magnitude transmission unit 250 transmits the magnitude of the synthesized sound by using an IR channel, the sound magnitude reception unit 150 may use an IR signal reception apparatus. If the magnitude of the synthesized sound is transmitted through an RF channel, the sound magnitude reception unit 150 may use an RF signal reception apparatus.

The first control unit 160 controls the audio signal generation unit 110, the audio signal modification unit 120, and the sound beam generation unit 130 to repeatedly perform the transmission and reception operations. Accordingly, a filter coefficient to equalize a room parameter is obtained.

To obtain a filter coefficient, the present general inventive concept employs a method which differs from the conventional technology. In the conventional technology, a collected sound is analyzed, a room parameter is directly calculated, and by using the room parameter, a filter coefficient is obtained.

In contrast, the present general inventive concept does not obtain a room parameter. Instead, a filter coefficient to minimize the magnitude of the sound obtained through synthesis of the two sounds 2 and 4 is obtained among a plurality of filter coefficient values.

Accordingly, the first control unit 160 performs two processes.

The first process controls the two sounds 2 and 4 to arrive at the position of the listener at the same time. Since the sound 4, which is reflected by the reflecting object 20 and then arrives at the position of the listener travels a distance longer than that of the sound 2, which directly arrives at the position of the listener, a delay occurs in the sound 4. Accordingly, by delaying the sound 2 which directly arrives at the position of the listener for a period of time corresponding to a predetermined delay constant before outputting the sound 2, the two sounds 2 and 4 can arrive at the position of the listener at the same time. This is performed through a process to obtain a delay constant to make the magnitude of the synthesized sound a minimum value, in which operations to generate audio signals, to modify audio signals, to generate sound beams, and to determine a magnitude of a sound are iteratively performed with respect to a plurality of delay constants.

The second process includes obtaining a filter coefficient, while the delay constant determined in the first process is transferred to the delay unit 122 and an audio signal which corresponds to the sound to be directly transferred to the position of the listener is delayed.

In the second process, a filter coefficient to make the magnitude of the synthesized sound a minimum value is obtained by iteratively performing operations to generate audio signals, to modify audio signals, to generate sound beams, and to determine a magnitude of a sound with respect to a plurality of delay constants.

After the second process completes and an audio signal is reproduced, the determined filter coefficient is used and a sound by which a room parameter is equalized can be provided to the listener.

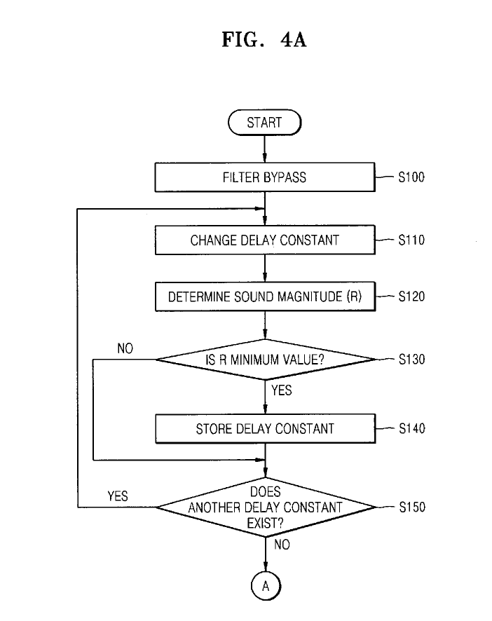

Referring to FIG. 3, each operation of the method of equalizing a room parameter will now be explained in more detail with respect to FIGS. 4A and 4B. FIGS. 4A and 4B are a flowchart of a method of equalizing a room parameter according to an embodiment of the present general inventive concept.

FIG. 4A illustrates the first process performed in the first control unit 160 as denoted above, i.e., the process of obtaining a delay constant.

Since a filter coefficient is not yet determined in the first process, the filter 126 is set to a bypass mode in operation S100. Accordingly, an audio signal corresponding to the sound 4 to be reflected is transferred to the sound beam generation unit 130 without change.

In the first control unit 160, one of a plurality of delay constant values is selected and the delay constant of the delay unit 122 is changed in operation S110. By using the selected delay constant, the process of generating audio signals, modifying audio signals, generating sound beams and determining the magnitude of a sound is performed in operation S120.

Operation S130 confirms whether the determined magnitude (R) of a synthesized sound is a minimum value in operation S130. If the determined magnitude (R) of a synthesized sound is a minimum value, the used delay constant is stored in operation S140. If the determined magnitude (R) of a synthesized sound is not a minimum value, the used delay constant is not stored.

Operation S150 confirms whether another delay constant exists. If another delay constant exists, operations S110 through S140 are repeatedly performed with respect to the delay constant.

By performing the first process, a delay constant that controls the two sounds 2 and 4 to arrive at the position of the listener at the same time can be found.

FIG. 4B illustrates the second process performed in the first control unit 160 as denoted above, i.e., the process of finding a filter coefficient.

The delay constant found in the first process is set as a delay constant to be used in the delay unit 122 in operation S200.

One of a plurality of filter coefficient values is selected and the filter coefficient of the filter 126 is changed in operation S210.

Using the selected filter coefficient, the process of generating audio signals, modifying audio signals, generating sound beams and determining the magnitude of a sound is performed in operation S220.

Operation S230 confirms whether the determined magnitude (R) of a synthesized sound is a minimum value. If the determined magnitude (R) of a synthesized sound is a minimum value, the used filter coefficient is stored in operation S240. If the determined magnitude (R) of a synthesized sound is not a minimum value, the user filter coefficient is not stored.

Operation S250 confirms whether another filter coefficient exists. If another filter coefficient exists, operations S210 through S240 are repeatedly performed with respect to the filter coefficient.

By performing the second process, a filter coefficient that makes the sound 4 that is affected by a reflecting object produces an identical waveform as that of the sound 2 which directly arrives at the position of the listener.

A principle in which a room parameter is equalized when a sound generated through synthesis of the two sounds 2 and 4 of FIG. 3 has a minimum magnitude will now be explained.

FIG. 5 is a diagram illustrating examples of waveforms of sounds generated in the sound beam generation unit 130, the waveforms appearing at the position of a listener, according to an embodiment of the present general inventive concept.

Referring to FIG. 3, after the sound 2 is generated from an audio signal delayed in the delay unit 122 and inverted in the inverter 124, and is output to the listener, if the sound 2 arrives at the sound collection unit 21, the sound 2 has a waveform as indicated by reference number 7.

After the sound 4 generated by an audio signal equalized by the filter 126 is reflected by the reflecting object 20, if the sound 4 arrives at the sound collection unit 210 disposed at the position of the listener, the sound 4 has a waveform as indicated by reference number 8.

A comparison of two waveforms 7 and 8 illustrates that the two waveforms 7 and 8 have same magnitudes but opposite phases. Accordingly, the sound synthesized with the two sounds 2 and 4 has a waveform having a value close to 0 as indicated by reference number 9.

However, the present general inventive concept does not require the magnitude of the synthesized sound to be 0. Instead, a delay constant and filter coefficient that make the magnitude of a synthesized sound a minimum value are found among given delay constants and filter coefficients. Accordingly, unlike the conventional technology requiring a high-precision microphone, the sound collection unit 210 according to the present general inventive concept can be implemented with a low-priced microphone.

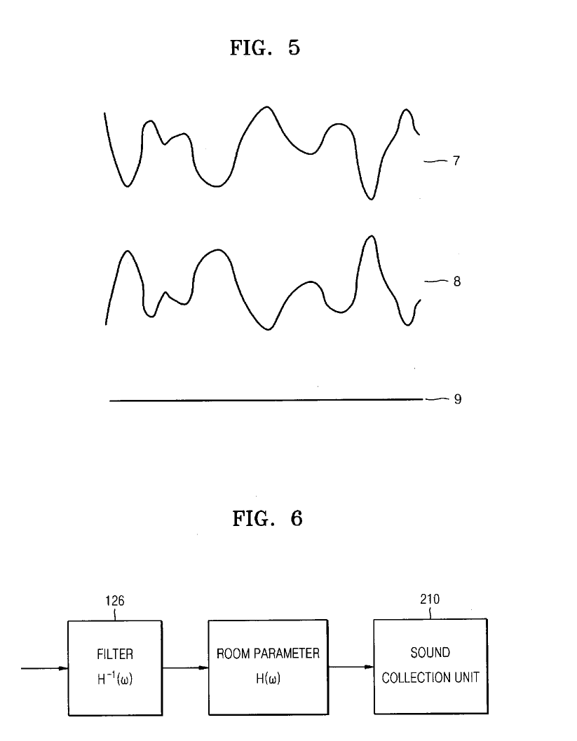

FIG. 6 is a diagram illustrating a process of equalizing a room parameter by the filter 126 according to an embodiment of the present general inventive concept.

Referring to FIG. 6, assuming that a function of a room parameter is H(ω), a function of H⁻¹ (ω) may be set as a filter coefficient in the filter 126. Since the filter 126 completely equalizes the room parameter, the synthesized sound collected in the sound collection unit 210 has a value close to 0.

Accordingly if a filter coefficient that makes the magnitude of the synthesized sound a minimum value is found among a plurality of filter coefficient values according to the current embodiment of the present general inventive concept, the filter coefficient has a value closest to H⁻¹ (ω).

As described above, according to the method and apparatus to equalize a room parameter of the present general inventive concept, a filter coefficient to equalize the room parameter can be obtained even without directly obtaining a room parameter that affects sound. Also, since only determination of a magnitude of the synthesized sound is required, the room parameter can be equalized with a simple structure and low cost. Furthermore, since only measuring the magnitude of the sound is required, it is possible to include a sound magnitude collection unit inside a remote controller. Accordingly, the listener avoids inconvenience of connecting wires.

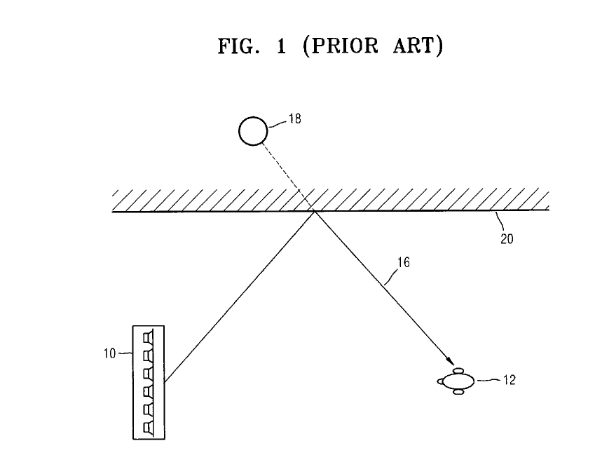

The method of equalizing a room parameter according to the present general inventive concept can be applied to a plurality of channels. FIG. 1 illustrates an example in which one sound beam is generated in the acoustic transducer array, and accordingly, the room parameter being equalized with respect to one channel (one sound beam) is described above.

However, an acoustic transducer array can output a plurality of beams, and a plurality of channels in which sounds arrive at the position of the listener according to relative orientations with respect to the reflecting object 20, such as a wall or ceiling, can be generated. For example, a left channel that outputs a sound beam which is reflected by a left-hand side wall can perform a role of a virtual left speaker, and a right channel that outputs a sound beam which is reflected by a right-hand side wall can perform a role of a virtual right speaker.

Accordingly, equalization of a room parameter according to the present general inventive concept can be performed with respect to each channel. The present general inventive concept can be easily applied to a plurality of channels by iteratively performing the process of finding a filter coefficient with respect to each channel.

According to the apparatus and method of equalizing a room parameter of the present general inventive concept, the magnitude of a synthesized sound is measured and a delay constant and a filter coefficient making the magnitude a minimum vale are obtained, thereby enabling with a simple structure and low cost, equalization of a room parameter by a reflecting object affecting the sound. Furthermore, since only measuring of the magnitude of the sound is required, it is possible to include a sound magnitude determination unit inside a remote controller, thereby allowing the listener to avoid inconvenience of connecting wires.

The present general inventive concept can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, and optical data storage devices.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An apparatus to equalize a room parameter in an audio system using an acoustic transducer array, the apparatus comprising:
an audio signal generation unit to generate two identical audio signals;
an audio signal modification unit to modify the audio signals, thereby generating the two signals to have opposite phases, with one of the two signals being delayed from the other signal for a time period corresponding to a predetermined delay constant and the other signal being filtered;
a sound beam generation unit to receive the two modified signals from the audio signal modification unit, to transform each of the two modified signals into a sound, and to directly transmit one sound to a position of a listener and to transmit the other sound to the position of the listener such that the other sound is reflected from a reflecting object before being transmitted to the position of the listener;
a sound magnitude determination unit to collect a sound generated through synthesis of the two sounds at the position of the listener and determining a magnitude of the sound; and
a control unit to obtain a delay constant and a filter coefficient to make the magnitude of the synthesized sound a minimum value among a plurality of delay constant values and filter coefficient values, by making the audio signal generation unit, the audio signal modification unit, the sound beam generation unit, and the sound magnitude determination unit iteratively operate.

2. The apparatus of claim 1, wherein the control unit comprises:
a delay constant determination unit to obtain a delay constant to make the magnitude of the synthesized sound a minimum, by iteratively performing the operations with respect to the plurality of delay constant values; and
a filter coefficient determination unit to obtain a filter coefficient to make the magnitude of the synthesized sound a minimum, by delaying an audio signal to generate a sound which is to be directly transferred to the position of the listener, by using the obtained delay constant, and by iteratively performing the operations with respect to the plurality of filter coefficient values.

3. The apparatus of claim 1, wherein the audio signal generation unit is an audio source of the audio system or a separate noise generator.

4. The apparatus of claim 1, wherein the audio signal modification unit comprises:
an inverter to invert the phase of one of the two audio signals generated in the audio signal generation unit;
a signal delay unit to delay one of the two audio signals for a time period corresponding to a predetermined delay constant; and
a filter to filter one of the two audio signals to equalize the room parameter.

5. The apparatus of claim 1, wherein the sound beam generation unit uses the acoustic transducer array of the audio system.

6. The apparatus of claim 1, wherein the sound magnitude determination unit is included in a remote controller of the audio system.

7. The apparatus of claim 1, wherein the sound magnitude determination unit comprises:
a sound collection unit to collect the synthesized sound and to convert the sound into an electrical signal;
a sound magnitude measuring unit to measure a magnitude of the electrical signal;
an analog-to-digital converter (ADC) to convert the measured magnitude of the sound into digital information; and
a sound magnitude transmission unit to transmit the determined magnitude of the sound to the main system of the audio system.

8. The apparatus of claim 7, wherein the sound collection unit is a microphone.

9. The apparatus of claim 7, wherein the sound magnitude measuring unit comprises:
a root mean square (RMS) value measuring unit to measure an RMS value of the synthesized sound.

10. The apparatus of claim 7, wherein the sound magnitude transmission unit transmits the determined magnitude of the sound by using an infrared channel or a radio frequency (RF) channel.

11. A method of equalizing a room parameter in an audio system using an acoustic transducer array, the method comprising:
generating two identical audio signals having opposite phases, with one of the two signals being delayed from the other signal for a time period corresponding to a predetermined delay constant and the other signal being filtered;
transforming each of the two modified signals into a sound, and directly transmitting one sound to the position of a listener and transmitting the other sound to the position of the listener such that the other sound is reflected from a reflecting object and transmitted to the position of the listener;
collecting a sound generated through synthesis of the two sounds at the position of the listener and determining a magnitude of the sound; and
obtaining a delay constant and a filter coefficient making the magnitude of the synthesized sound a minimum, by performing operations to generate the audio signals, to transmit the sounds, and to determine the magnitude of the sound, iteratively performed with respect to a plurality of delay constant values and filter coefficient values.

12. The method of claim 11, wherein the obtaining of the delay constant and filter coefficient comprises:
obtaining a delay constant making the magnitude of the synthesized sound a minimum, among the plurality of delay constant values; and
obtaining a filter coefficient making the magnitude of the synthesized sound a minimum, among the plurality of filter coefficient values, by delaying an audio signal to generate a sound which is to be directly transferred to the position of the listener, with using the obtained delay constant.

13. The method of claim 11, wherein the determining of the magnitude of the synthesized sound is performed in a remote controller of the audio system.

14. The method of claim 11, further comprising:
transmitting the determined magnitude of the sound to the main system of the audio system.

15. The method of claim 15, wherein the transmitting of the determined magnitude of the sound comprises;
transmitting the determined magnitude of the sound by using an infrared channel which is generally used in the remote controller of the audio system to transmit a command to control the audio system.

16. The method of claim 14, wherein the transmitting of the determined magnitude of the sound comprises:
transmitting the determined magnitude of the sound by using a radio frequency (RF) channel.

17. The method of claim 11, wherein the determining of the magnitude of the synthesized sound comprises:
measuring the magnitude of the synthesized sound; and
converting the measured magnitude of the sound into digital information.

18. The method of claim 17, wherein the measuring of the magnitude of the synthesized sound comprises:
measuring a root square mean (RMS) value of the synthesized sound.

19. The method of claim 11, wherein the reflecting object is a wall or a ceiling of a room.

20. A computer readable recording medium having embodied thereon a computer program to execute a method wherein the method comprises:
generating two identical audio signals having opposite phases, with one of the two signals being delayed from the other signal for a time period corresponding to a predetermined delay constant and the other signal being filtered;
transforming each of the two modified signals into a sound, and directly transmitting one sound to the position of a listener and transmitting the other sound to the position of the listener such that the other sound is reflected from a reflecting object and transmitted to the position of the listener;
collecting a sound generated through synthesis of the two sounds at the position of the listener and determining a magnitude of the sound; and
obtaining a delay constant and a filter coefficient making the magnitude of the synthesized sound a minimum, by making operations to generate the audio signals, transmitting the sounds, and determining the magnitude of the sound, iteratively performed with respect to a plurality of delay constant values and filter coefficient values.

21. An apparatus to equalize a room parameter in an audio system using an acoustic transducer array, the apparatus comprising:
an audio signal generation unit to generate two identical audio signals;
an audio signal modification unit to modify the audio signals, thereby generating the two signals to have opposite phases, with one of the two signals being delayed from the other signal for a time period corresponding to a predetermined delay constant and the other signal being filtered;
a sound beam generation unit to receive the two modified signals from the audio signal modification unit to transform each of the two modified signals into a sound, and to directly transmit one sound to a position of a listener and to transmit the other sound to the position of the listener such that the other sound is reflected from a reflecting object before being transmitted to the position of the listener;
a sound magnitude reception unit to receive a magnitude determined at the position of the listener, of the sound generated through synthesis of the two sounds; and
a control unit to obtain a delay constant and a filter coefficient to make the magnitude of the synthesized sound a minimum among a plurality of delay constant values and filter coefficient values, by making the audio signal generation unit, the audio signal modification unit, the sound beam generation unit and the sound magnitude reception unit, iteratively operate,
wherein the apparatus is included in the main system of the audio system.

22. An apparatus to determine a magnitude of a synthesized sound to equalize a room parameter in an audio system using an acoustic transducer array, the apparatus comprising:
a sound collection unit to collect a sound generated through synthesis of two sounds transferred to a position of a listener and to convert the sound into an electrical signal;
a sound magnitude measuring unit to measure a magnitude of the electrical signal;
an analog-to-digital converter (ADC) to convert the measured magnitude of the sound into digital information; and
a sound magnitude transmission unit to transmit the determined magnitude of the sound to the main system of the audio system,
wherein the apparatus is included in a remote controller of the audio system.

23. A method of equalizing a room parameter in an audio system using an acoustic transducer array, the method comprising:
generating two identical audio signals having opposite phases, with one of the two signals being delayed from the other signal for a time period corresponding to a predetermined delay constant and the other signal being filtered;
transforming each of the two modified signals into a sound, and directly transmitting one sound to the position of a listener and transmitting the other sound to the position of the listener such that the other sound is reflected from a reflecting object and transmitted to the position of the listener;
receiving the magnitude determined at the position of the listener, of the sound generated through synthesis of the two sound; and
obtaining a delay constant and a filter coefficient making the magnitude of the synthesized sound a minimum by making operations to generate the audio signals, to transmit the sounds to the position of the listener, and to receive the magnitude of the synthesized sound, iteratively performed with respect to a plurality of delay constant values and filter coefficient values,
wherein the method is performed in the main system of the audio system.

24. A method of determining the magnitude of a synthesized sound to equalize a room parameter in an audio system using an acoustic transducer array, the method comprising:
collecting a sound generated through synthesis of two sounds transferred to the position of a listener and determining the magnitude of the sound; and
transmitting the determined magnitude of the sound to the main system of the audio system,
wherein the method is performed in a remote controller of the audio system.

25. An apparatus to equalize a room parameter in an audio system using an acoustic transducer array, the apparatus comprising:
an audio signal modification unit to modify two identical audio signals to generate two signals having opposite phases, wherein one of the signals is delayed;
a sound beam generation unit to transform each of the two modified signals into a sound, and to directly transmit the sound corresponding to the delayed signal to a position of a listener and to transmit the other sound to the position of the listener such that the other sound is reflected from a reflecting object before being transmitted to the position of the listener;
a sound magnitude determination unit to synthesize the two sounds at the position of the listener and to determine a magnitude of the synthesized sound; and
a control unit to obtain a delay constant and a filter coefficient to make the magnitude of the synthesized sound a minimum value among a plurality of delay constant values and filter coefficient values.

26. An apparatus to equalize a room parameter in an audio system using an acoustic transducer array the apparatus comprising:
a sound beam generation unit to generate a first sound beam and a second sound beam from a first modified sound signal and a second modified sound signal;
a control unit to control the first sound beam and the second sound beam to arrive at a position of a listener at the same time, wherein the first sound beam travels directly to the listener, and to obtain a filter coefficient to produce a minimum magnitude of a sound that is produce by combining the first sound beam and the second sound beam.

27. The apparatus of claim 26, wherein the second sound beam reflects from an object before arriving at the position of the listener.

28. The apparatus of claim 27, wherein the control unit delays the first sound for a time period corresponding to a delay constant, so that the first sound beam and the second sound beam arrive at the position of the listener at the same time.

29. A method of equalizing a room parameter in an audio system using an acoustic transducer array, the method comprising:
modifying two identical audio signals to generate two signals having opposite phases, wherein one of the signals is delayed;
transforming each of the two modified signals into a sound;
transmitting the sound corresponding to the delayed signal to a position of a listener and transmitting the other sound to the position of the listener such that the other sound is reflected from a reflecting object before being transmitted to the position of the listener;
synthesizing the two sounds at the position of the listener
determining a magnitude of the synthesized sound; and
obtaining a delay constant and a filter coefficient to make the magnitude of the synthesized sound a minimum value among a plurality of delay constant values and filter coefficient values.

30. A method of equalizing a room parameter in an audio system using an acoustic transducer array the method comprising:
generating a first sound beam and a second sound beam from a first modified sound signal and a second modified sound signal;
controlling the first sound beam and the second sound beam to arrive at a position of a listener at the same time, wherein the first sound beam directly travels to the listener; and
obtaining a filter coefficient to produce a minimum magnitude value of a sound that is produced by combining the first sound beam and the second sound beam.

31. The method of claim 30, wherein the producing of the minimum magnitude value of the combined sound beams is performed by obtaining the filter coefficient by iteratively performing operations to generate audio signals, to modify audio signals, to generate sound beams, and to determine a magnitude of a sound with respect to a plurality of delay constants.
